(19) United States
(12) Patent Application Publication
(10) Pub. No.: US 2018/0122777 A1
(43) Pub. Date: May 3, 2018

(54) HYBRID MICRO-CIRCUIT DEVICE WITH STACKED CHIP COMPONENTS

(71) Applicant: Raytheon Company, Waltham, MA (US)

(72) Inventors: Tse E. Wong, Los Alamitos, CA (US); Samuel D. Tonomura, Rancho Palos Verdes, CA (US); Stephen E. Sox, La Canada, CA (US)

(21) Appl. No.: 15/339,208

(22) Filed: Oct. 31, 2016

(51) Int. Cl. H01L 25/065; H01L 23/31; H01L 23/367; H01L 29/161; H01L 29/20

(52) U.S. Cl. CPC H01L 25/0657; H01L 23/3114; H01L 2225/06513; H01L 29/161; H01L 29/20; H01L 23/367

(57) ABSTRACT

A hybrid micro-circuit device has multiple layers overlying a printed circuit board (PCB), including a first semiconductor chip component that is electrically connected to the PCB, and a second semiconductor chip component that is electrically connected to first semiconductor chip component. A molding compound surrounds the stack of components that includes the semiconductor chip components. This molding compound may include pillars that are higher than the height of the stacked components. The pillars of molded material may be configured to receive most of the stress from other components over the stacked components. The pillars of molded material may also help define a recess between the stack components and the other components that overlie the stacked components, where a thermal interface material (TIM) may be located. Further, there may be an air gap between parts of the semiconductor chip components.

### FIELD OF THE INVENTION

The invention is in the field micro-circuit devices with multiple components.

### DESCRIPTION OF THE RELATED ART

Micro-circuit devices have had increased density of components over time. This increased density of devices raises issues of heat removal and performance degradation.

### SUMMARY OF THE INVENTION

A hybrid micro-circuit device has a recess therein, between one or more components, and one or more overlying components, for receiving a thermal interface material.

A hybrid micro-circuit device has an air gap between electrical components, with the air gap surrounded by a molding compound.

A hybrid micro-circuit device has an air gap between stacked components that are electrically coupled together.

A hybrid micro-circuit device has an air gap, and damming elements around the air gap that prevent ingress of molding compound.

According to an aspect of the invention, a hybrid micro-circuit device includes: a printed circuit board; a first semiconductor chip component overlying and electrically coupled to the printed circuit board; a second semiconductor chip component overlying and electrically coupled to the first semiconductor chip component, whereby the first semiconductor chip component and the second conductor semiconductor chip component constitute stacked semiconductor chip components; molding compound around the stacked semiconductor chip components; and a structure resting on pillars of the molding compound that rise above the stacked semiconductor chip components.

According to an embodiment of any paragraph(s) of this summary, the first semiconductor chip component is a multilayer SiGe die.

According to an embodiment of any paragraph(s) of this summary, the second semiconductor chip component is a GaAs die.

According to an embodiment of any paragraph(s) of this summary, the structure includes a heat spreader.

According to an embodiment of any paragraph(s) of this summary, the structure includes a cover.

According to an embodiment of any paragraph(s) of this summary, the structure, the molding compound, and the second semiconductor chip component define a recess.

According to an embodiment of any paragraph(s) of this summary, the device further includes a thermal interface material (TIM) in the recess, thermally coupled to both the second semiconductor chip component and the structure.

According to an embodiment of any paragraph(s) of this summary, the structure includes a heat spreader that is in contact with the thermal interface material.

According to an embodiment of any paragraph(s) of this summary, the structure further includes a cover that overlies the heat spreader.

According to an embodiment of any paragraph(s) of this summary, the device further includes an additional thermal interface material between the heat spreader and the cover, and in contact with both the heat spreader and the cover.

According to an embodiment of any paragraph(s) of this summary, a top surface of the pillars is at least 0.1 mm further from the printed circuit board than a top surface of the second semiconductor chip component.

According to an embodiment of any paragraph(s) of this summary, there is an air gap between the first semiconductor chip component and the second semiconductor chip component, surrounded by the molding compound.

According to another aspect of the invention, a hybrid micro-circuit device includes: a printed circuit board; a first semiconductor chip component overlying and electrically coupled to the printed circuit board; a second semiconductor chip component overlying and electrically coupled to the first semiconductor chip component, whereby the first semiconductor chip component and the second conductor semiconductor chip component constitute stacked semiconductor chip components; and molding compound around the stacked semiconductor chip components; wherein there is an air gap between the first semiconductor chip component and the second semiconductor chip component, surrounded by the molding compound.

According to an embodiment of any paragraph(s) of this summary, the air gap has a height of 0.1 mm to 0.2 mm.

According to an embodiment of any paragraph(s) of this summary, the device further includes solder balls electrically coupling the first semiconductor chip component to the second conductor semiconductor chip component.

According to an embodiment of any paragraph(s) of this summary, the solder balls are interspersed within the air gap.

According to an embodiment of any paragraph(s) of this summary, the device further includes damming elements around the air gap, wherein the damming elements prevent ingress of the molding compound into the air gap and/or the second semiconductor chip.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

The annexed drawings, which are not necessarily to scale, show various aspects of the invention.

FIG. 1 is a first oblique view of a hybrid micro-circuit device in accordance with an embodiment of the present invention.

FIG. 2 is a second oblique view of the hybrid micro-circuit device of FIG. 1.

FIG. 3 is a cross-sectional view of a portion of the hybrid micro-circuit device of FIG. 1.

FIG. 4 is a cross-sectional view of a portion of a hybrid micro-circuit device in accordance with an alternate embodiment of the present invention.

### DETAILED DESCRIPTION

A hybrid micro-circuit device has multiple layers overlying a printed circuit board (PCB), including a first semiconductor chip component (a multilayer silicon-germanium (SiGe) die) that is electrically connected to the PCB, and a second semiconductor chip component (e.g., a gallium-arsenide (GaAs) chip or die) that is electrically connected to first semiconductor chip component. A molding compound surrounds the stack of components that includes the semiconductor chip components. This molding compound may include pillars that are higher than the height of the stacked components. The pillars of molded material may be configured to receive most of the stress from other components over the stacked components, such as a heat spreader and/or cover. This may aid in protecting the stacked components from stresses that could damage the stacked components and/or affect electrical connections made by the stacked components. The pillars of molded material may also help define a recess between the stack components and the other components that overlie the stacked components, where a thermal interface material (TIM) may be located. The presence of pillars higher than the top of the stacked components aids in defining a recess that keeps the TIM from being squeezed out of the region between the stacked components and an overlying component, such as a heat spreader.

Further, there may be an air gap between parts of the stacked components (e.g., the SiGe die and the GaAs chip or die), which this air gap surrounded by the molding compound material. This air gap may help improve performance of the hybrid micro-circuit device, for example by reducing or eliminating performance degradation caused by the presence of solid material (dielectric material) in the gap. Obstructions, such as die dams (damming elements), may be placed around part or all of the periphery of the electrical connection region between the SiGe die and the GaAs die, to prevent ingress of the molding compound.

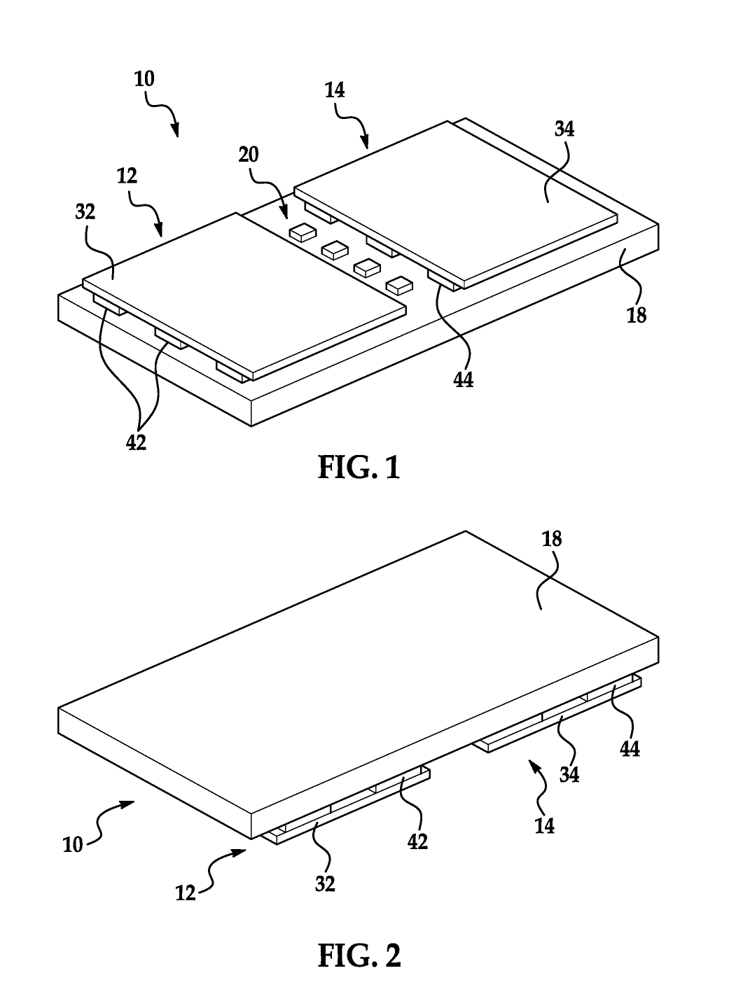

FIGS. 1 and 2 show a hybrid micro-circuit device 10 that includes a pair of chip packages 12 and 14. The device 10 may for example be used for radio frequency (RF) communication. The device 10 includes as a substrate a printed wiring board (PWB) or printed circuit board (PCB) 18 atop a heat sink (not shown in FIGS. 1 and 2). The PWB 18 may be adhesively joined to the heat sink. The PWB or PCB 18 contains conductive traces for making various electrical connections between components that are electrically coupled to various parts of the PWB or PCB 18. These components may include components that are parts of the chip packages 12 and 14, as explained further below. The components may also include other electronic components 20 that are mounted on the PWB or PCB 18 outside of the chip packages 12 and 14. The PCB 18 also may include integrally formed components that are an integral part of the PCB 18.

The packages 12 and 14 include respective covers 32 and 34 that cover over (overlie) respective groups of package components 42 and 44 that are directly or indirectly coupled to the PCB or PWB 18. The package components 42 and 44 may include chips or other components.

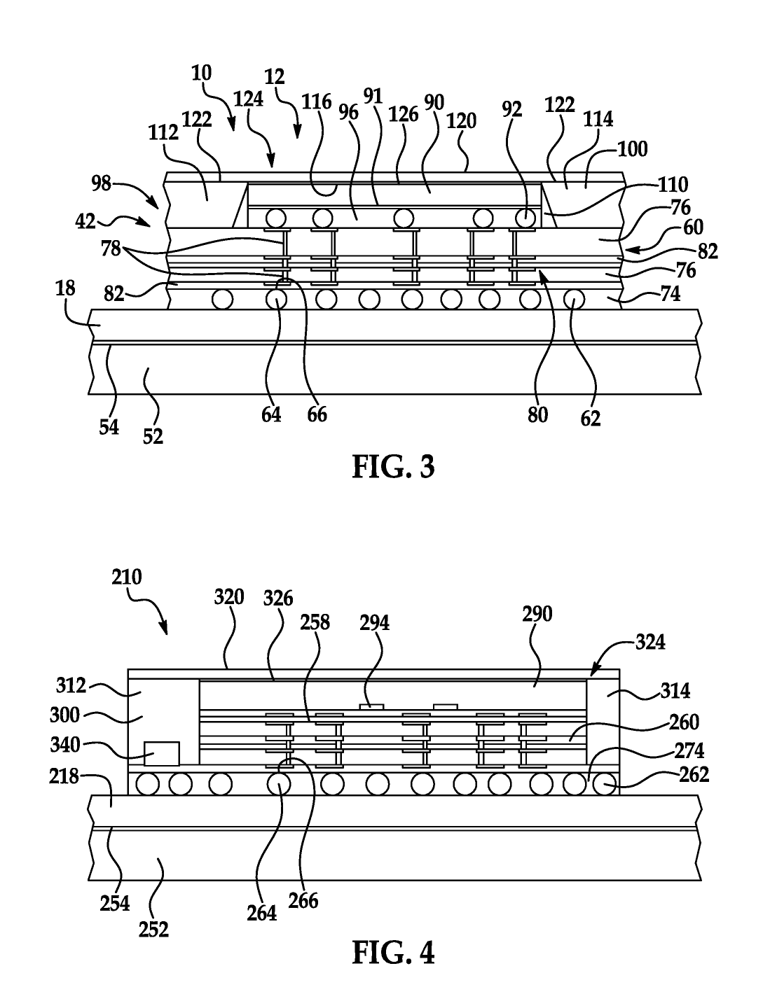

FIG. 3 shows a part of hybrid micro-circuit device 10, showing the details of part of one of the chip package 12. In this view a heat sink 52 is shown coupled to the PWB 18 by an adhesive layer 54. The heat sink 52 and the adhesive layer 54 are optional, and may be omitted if desired.

A multiplayer silicon germanium (SiGe) die 60 (one of the package components 42, an example of a semiconductor chip component) is electrically coupled to the PWB 18 through a series of eutectic solder balls 62. The solder balls 62 make electrical connection between contact pads 64 on the PWB 18 and corresponding contact pads 66 on the die 60. The solder balls 62 may be added to the SiGe die 60 after formation of the die 60, and the solder balls 62 may be heated and reflowed with the die 60 in place on the PWB 18, to electrically couple the die 60 to the PWB or PCB 18. An underfill 74 may be used to fill in the spaces between and around the solder balls 62.

The SiGe die 60 has two or more layers 76 that are electrically coupled together through conductive vias (through-silicon vias (TSVs)) 78 in the layers 76, which are joined by a direct bond interconnect (DBI) process, forming a DBI 80. This allows electrical/electronic components overlying the SiGe die 60 to make electrical connection with parts of the die 60, as well as with parts of the PCB 18. The vias 78 may be generated by such methods as mechanical drilling, laser beam drilling, etching methods, stamping, or other suitable methods, and then are filled with electrically-conductive materials, such as copper, tungsten, or organic conductors (to give a few examples).

There also may be redistribution layers (RDLs) 82 between adjacent of the layers 76 and/or on the faces of the multiplayer die 60. The RDLs 82 include metal layers that facilitate electrical connection to and/or between the vias, contact pads, and other electrical traces and/or parts of the layers 76. Contact pads, conductive vias, and/or RDLs may be made of any of a variety of suitable electrically conductive materials, such as (for example) aluminum, gold, copper, metal alloys, or organic conductors. The layers 76 of the SiGe die 60 may be coupled together using known wafer-to-wafer bonding techniques.

A GaAs die 90 (another of the package components 42, and another example of a semiconductor chip component) overlies and is electrically coupled to the multilayer SiGe die 60. The GaAs die 90 may be or may include a chip that is electrically coupled to the SiGe die 60 in a flip-chip configuration. Such semiconductor chips may have contact pads which allow electrical contact to be made with the semiconductor chip. The contact pads may be composed of any desired electrical conductive material, for example of a metal, such as aluminum, gold or copper, a metal alloy or an electrical conductive organic material. The contact pads may be situated on the active surfaces of the semiconductor chips or on other surfaces of the semiconductor chips. The GaAs die 90 may include a monolithic microwave integrated circuit (MMIC) wafer. An RDL 91 may also be on the face of the GaAs die 90.

Solder balls or bumps 92, which may be fabricated as parts of the GaAs die 90, may be used to electrically couple the GaAs die 90 to the multilayer SiGe die 60. Heating may be used after placement of the GaAs die 90 on the SiGe die 60 to melt and reflow the solder bumps 92, to make an electrically connection between the dies 60 and 90.

There may be an air cavity 96 between and around the solder balls 92, and between the dies 60 and 90. This air cavity 96 may help avoid signal degradation between the dies 60 and 90, which together constitute stacked components 98 that overlie the PCB 18.

A molding compound 100 surrounds the stacked components 98. The molding compound 100 encapsulates the components 42, protecting and supporting in particular the stacked components 98. The molding compound 100 may contain organic resins, such as an epoxy resin. The molding compound 100 may also contain fill materials such as small particles of glass (SiO₂), or other electrically insulating mineral filler materials like Al₂O₃, or organic filler materials. Such fill materials may be included to achieve desired properties, such as a desired coefficient of thermal expansion. Other materials, such as catalysts, flame retardants, ion traps, adhesion promoters, and/or stress relievers may be added to the molding compound as appropriate.

Damming elements 110 are placed around the periphery of the air cavity 96, to prevent the molding compound 100, which is deposited subsequent to the placement of the damming elements 110, from getting into the air cavity 96. The damming elements 110 may be made of a suitable thermoplastic of thermosetting material, or any of a variety of other suitable materials. The damming elements 110 may be triangular in shape, as shown in the illustrated embodiment, or may have other suitable shapes. As also shown, the damming elements 110 may rest on a top surface of the SiGe die 60, a circumferential portion of this top surface that extends outwardly beyond the central part of the upper or top surface that the GeAs die 90 overlies.

Pillars 112 and 114 of the molding compound 100 may be built up above the level of a top surface 116 of the GaAs die 90. This allows the molding compound 100 to mechanically support layers or components of the device 10 that overlie the stacked components 98. In FIG. 3 a heat spreader 120 is one such overlying component. Another example of a component that may overlie the stacked components 98 is a cover, such as the cover 32 shown in FIG. 1. As an alternative to the embodiment illustrated in FIG. 3, a cover may be directly attached to the pillars 112 and 114. An adhesive 122 on top of the pillars 112 and 114 may be used to attach the heat spreader 120 to the molding compound 100. The heat spreader 120 may be made of a thermally-conductive material, such as a suitable metal, and may be used to conduct heat away from the dies 60 and 90. The heat spreader 120 may increase conduction of heat by about 40%, relative to placing molding compound over the stacked components 98.

The tops of the pillars 112 and 114 are further from the PWB 18 than the top 116 of the stacked components 98. This helps define a recess 124 between the stacked components 98 and the heat spreader 120. The recess 124 is bounded at the bottom by the stacked components 98, at the top by the heat spreader 120, and along the sides by the top portions of the pillars 112 and 114. The recess is used for receiving a thermal interface material (TIM) 126 that facilitates heat transfer between the stacked components 98 and the heat spreader 120. Such TIMs may be materials with a polymerizable liquid matrix (e.g., epoxies, silicones, urethanes, and/or acrylates) and large volume fractions of electrically insulating/conductive, but thermally conductive filler (e.g., aluminum oxide, boron nitride, zinc oxide, and/or aluminum nitride. The recess 124 may have a height of 0.1 mm to 0.2 mm, or may have another height compliant with thermal and/or structural requirements. The recess 124 helps contain the TIM 126, keeping the TIM from being squeezed out of the space between the heat spreader 120 and the stacked components 98, when the heat spreader 120 is put into place.

Several features of the hybrid micro-circuit device 10 lead to improved performance. The molding compound pillars 112 and 114 take the stress of overlying layers such as the heat spreader 120. This avoids placing mechanical stresses on the stacked components 98, which may help avoid damage to the components 98 or performance degradation.

The air cavity 96 also may result in improved performance of the stacked components 98 in general, and the GaAs die 90 in particular. This air cavity or gap 96 can reduce the electrical loss because the dielectric constant is much lower when having an air cavity (compared with having other types of materials). This may mitigate the consequence of detuning the desirable performance (or the field failing to deliver a repeatable process).

The hybrid micro-circuit device 10 may have additional components, for example a capacitor (not shown) that is separately electrically couple to the PWB 18. The capacitor may be encapsulated in the molding compound 100.

The hybrid micro-circuit device 10 may be used for any of a variety of purposes. Once possible application is for radio frequency (RF) communication devices, but it will be appreciated that alternatively the configuration may be used for any of a variety of other micro-circuit devices used for other purposes, and/or digital/analog devices for military and commercial applications.

Many alternatives are possible for the embodiment shown in FIGS. 1-3 and described above. There may be different numbers of components, different types of components, and/or different arrangements of components than what is shown in the illustrated embodiment. In other words, the feature described above may be usable in any of a variety of stacked chip packages where dielectric loss, thermal performance, and/or structural integrity are concern(s).

FIG. 4 shows a portion of an alternative embodiment hybrid micro-circuit device 210. Many of the elements of the hybrid micro-circuit device 210 are similar to those in the portion of the device 10 that is shown in FIG. 3, and the description of similar features is largely omitted.

The main difference between the hybrid micro-circuit device 210 shown in FIG. 4 and the hybrid micro-circuit device 10 (FIG. 3) is that the hybrid micro-circuit device 210 has a direct bond interconnect (DBI) or wafer-to-wafer connection 258 between the multilayer SiGe die 260 and the GaAs die 290. This is in contrast to the solder balls 92 (FIG. 3) that are used to couple the multilayer SiGe die 60 (FIG. 3) and the GaAs die 90 (FIG. 3). The DBI connection 258 leaves a series of air channels 294 between the SiGe die 260 and the GaAs die 290. The air channel 294 can reduce the electrical loss because the dielectric constant is much lower when having an air cavity, and this can mitigate the consequence of detuning the desirable performance (or the field failing to deliver a repeatable process).

In other regards structures of portion of the hybrid micro-circuit device 210 shown in FIG. 4 may be similar to corresponding parts of the hybrid micro-circuit device 10 (FIG. 3). Thus the hybrid micro-circuit device 210 may include a PWB or PCB 218, a heat sink 252, an adhesive layer 254, a series of eutectic solder balls 262, contact pads 264 and 266, an underfill 274, a molding compound 300, pillars 312 and 314, a heat spreader 320, a thermal interface material (TIM) 326 in a recess 324, and a capacitor (or other components) 340.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

1. A hybrid micro-circuit device comprising:
a printed circuit board;
a first semiconductor chip component overlying and electrically coupled to the printed circuit board;
a second semiconductor chip component overlying and electrically coupled to the first semiconductor chip component, whereby the first semiconductor chip component and the second conductor semiconductor chip component constitute stacked semiconductor chip components;
molding compound around the stacked semiconductor chip components; and
a structure resting on pillars of the molding compound that rise above the stacked semiconductor chip components.

2. The device of claim 1, wherein the first semiconductor chip component is a multilayer SiGe die.

3. The device of claim 1, wherein the second semiconductor chip component is a GaAs die.

4. The device of claim 1, wherein the structure includes a heat spreader.

5. The device of claim 1, wherein the structure includes a cover.

6. The device of claim 1, wherein the structure, the molding compound, and the second semiconductor chip component define a recess.

7. The device of claim 6, further comprising a thermal interface material (TIM) in the recess, thermally coupled to both the second semiconductor chip component and the structure.

8. The device of claim 7, wherein the structure includes a heat spreader that is in contact with the thermal interface material.

9. The device of claim 8, wherein the structure further includes a cover that overlies the heat spreader.

10. The device of claim 9, further comprising an additional thermal interface material between the heat spreader and the cover, and in contact with both the heat spreader and the cover.

11. The device of claim 1, wherein a top surface of the pillars is at least 0.1 mm further from the printed circuit board than a top surface of the second semiconductor chip component.

12. The device of claim 1, wherein there is an air gap between the first semiconductor chip component and the second semiconductor chip component, surrounded by the molding compound.

13. A hybrid micro-circuit device comprising:
a printed circuit board;
a first semiconductor chip component overlying and electrically coupled to the printed circuit board;
a second semiconductor chip component overlying and electrically coupled to the first semiconductor chip component, whereby the first semiconductor chip component and the second conductor semiconductor chip component constitute stacked semiconductor chip components; and
molding compound around the stacked semiconductor chip components;
wherein there is an air gap between the first semiconductor chip component and the second semiconductor chip component, surrounded by the molding compound.

14. The device of claim 13, wherein the air gap has a height of 0.1 mm to 0.2 mm.

15. The device of claim 13, wherein the first semiconductor chip component is a multilayer SiGe die.

16. The device of claim 13, wherein the second semiconductor chip component is a GaAs die.

17. The device of claim 13, further comprising solder balls electrically coupling the first semiconductor chip component to the second conductor semiconductor chip component.

18. The device of claim 17, wherein the solder balls are interspersed within the air gap.

19. The device of claim 13, further comprising damming elements around the air gap, wherein the damming elements prevent ingress of the molding compound into the air gap.
